(19) United States
(12) Patent Application Publication
(10) Pub. No.: US 2005/0170665 A1
(43) Pub. Date: Aug. 4, 2005

(54) Method of forming a high dielectric film

(75) Inventor: Yoshihiro Sugita, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/098,395

(22) Filed: Apr. 5, 2005

Related U.S. Application Data
(63) Continuation of application No. PCT/JP03/04919, filed on Apr. 17, 2003.

(51) Int. Cl. H01L 21/8242; H01L 21/31

(52) U.S. Cl. 438/780; 438/591; 438/240

(57) ABSTRACT

A method of forming a high-K dielectric film by the MOCVD method using an amine-based organic metal compound precursor is disclosed. According to the present method, a precursor gas including organic metal compound molecules of the amine-based organic metal compound precursor is supplied to a processing space that accommodates a substrate to be processed, the surface of the substrate being exposed so that the amine-base organic metal compound molecules are chemically adsorbed onto the surface of the substrate. Then, a hydrogen gas is supplied to the surface of the substrate, and an oxidization gas is introduced into the processing space to thereby form the high-K dielectric film on the surface of the substrate.

### CROSS REFERENCE TO RELATED APPLICATIONS

This application is a U.S. continuation application filed under 35 USC 111 (a) claiming benefit under 35 USC 120 and 365 (c) of PCT application JP2003/004919, filed on Apr. 17, 2003, the entire contents of which are hereby incorporated by reference.

### BACKGROUND OF THE INVENTION

1. Field of the Invention

The present invention generally relates to a method of forming a semiconductor device, and particularly to a method of forming a high dielectric film of a semiconductor device.

2. Description of the Related Art

Owing to the growing development of technology for miniaturizing the semiconductor device, presently, a super-miniaturized/high speed semiconductor device with a gate length of less than 0.1 μm can be fabricated. In order to realize high speed operation in such a super-miniaturized semiconductor device, the thickness of a gate dielectric film needs to be reduced to 1 nm or less according to the scaling rule. In the case of using a very thin gate dielectric film, a tunnel current may pass through the gate dielectric film causing an increase in the gate leak current.

To counter such a problem, it has been proposed in the prior art to use a so-called high-K dielectric film corresponding to a high dielectric film with a small equivalent oxide thickness (EOT) instead of a silicon oxide film that is conventionally used as a gate dielectric film. The high-K dielectric film may have a relatively thick physical thickness while having a small equivalent electric thickness with respect to a silicon oxide film. It is noted that the high-K dielectric film may correspond to a metal oxide film made of ZrO₂, HfO₂, or Al₂O₃ that has a high specific inductive capacity and a wide band gap, a metal silicate film made of ZrSiO4 or HfSiO4, or a metal aluminate film, for example.

The high-K dielectric film may also be used in a DRAM cell having a super-miniaturized memory cell capacitor to prevent an increase of a capacitor leak current by the tunnel current, and secure a sufficient capacitance in the memory cell capacitance, for example.

In the prior art, the high-K dielectric film may be formed through ALD (Atomic Layer Deposition) or MOCVD (Metal Oxide Chemical Vapor Deposition) using an organic metal compound precursor. In ALD, chemical adsorption of organic metal compound molecular precursor is conducted on a substrate to be treated, after which oxidation is conducted on the chemically adsorbed 1˜2 molecular thickness molecular precursor layer using an oxidation agent, and this process is repeatedly conducted to form multiple layers of 1˜2 molecular thickness precursor films to obtain a desired high-K dielectric layer.

As the organic metal compound precursor, amine-based material such as tetrakis(dimethylamino)hafnium (Hf[N(CH₃)₂]₄), tetrakis(diethylamino) hafnium (Hf[N(CH₂CH₃)₂]₄), tetrakis(dimethylamino)zirconium (Zr[N(CH₃)₂]₄), and tetrakis(diethylamino)zirconium (Hf[N(CH₂CH₃)₂]₄) may be used, for example.

However, these organic metal compounds contain organic functional groups in their molecules, and thereby, a large amount of carbon may remain in the fabricated high-K dielectric film.

Logically speaking, since a Hf—N bond is weaker than a N—C bond, when chemically adsorbed Hf[N(CH₃)₂]₄ molecules are reacted with an oxidation agent such ash H₂O, O₂, or O₃, a desired HfO₂ molecular layer is expected to be formed.

In other words, since the N—C bond contained in the organic reactant for realizing oxide reaction is more stable than the Hf—N bond contained in the molecular precursor, it is expected that the desired HfO₂ molecular film be formed without leaving carbon behind in the film.

However, as is described above, in the high-K dielectric film formed using the above organic compound precursors, carbon inevitably remains in the film due to the organic functional groups contained within the precursor molecules and as a result, defects are created in the film by the residual carbon. In a case where the residual carbon is removed through oxidation at a later process stage, dangling bonds may be created within the film. A film having such dangling bonds is unstable both from a dynamical perspective and a chemical perspective, and thereby leads to a decrease in reliability of a semiconductor device using such a high-K dielectric film. Also, the dangling bonds may lead to a decrease in the specific inductive capacity of the high-K dielectric film.

For example, in the prior art, when Hf[N(CH₃)₂]₄ and oxygen gas are used as precursors to form a HfO₂ film with a thickness of 3˜5 nm on a silicon substrate surface at a substrate temperature of 200˜550° C. by growing the film at a growth rate of a few nanometers per minute (nm/min) under a processing pressure of approximately 133 Pa (1 Torr), the concentration of the residual carbon contained in the film may reach up to 1×10²⁰ cm⁻³˜1×10²¹ cm⁻³ according to research conducted by the inventor of the present invention.

It is noted that a technique is known in the prior art for forming a high-K dielectric film that does not contain residual carbon. According to such a technique, a chloride precursor such as HfCl₄ or ZrCl₄ is used instead of an organic metal compound precursor. However, when a chloride precursor is used, chloride may remain in the formed high-K dielectric film to cause corrosion in the vicinity of the high-K dielectric film, for example.

It is known that amine-based organic compound materials are characterized by being highly reactive to hydrogen and are capable of inducing precipitation of metal or metal nitride compounds.

For example, in a case where Hf[N(CH₃)₂]₄ and hydrogen gas are combined, metal Hf or HfN may be precipitated by one of the following reactions:
Hf[N(CH₃)₂]₄+2H₂→Hf+4H−N(CH₃)₂ (1)
2Hf[N(CH₃)₂]₄+5H₂→2HfN+6H−N(CH₃)₂+4CH₄ (2)

In these reactions, the organic functional group may be desorbed from the metal element in a very efficient manner. Thereby, in forming a high-K dielectric film using an amine-based metal compound precursor, the organic functional groups are expected to be effectively desorbed during the metal molecular precipitation reaction of the surface of the substrate to be treated by doping hydrogen gas to the precursor.

However, it is difficult to control the above reactions (1) and (2), and generally, the reactions tend to occur in gas phase. Thereby, when hydrogen is simply doped into the precursor gas, a large amount of metal powder (particles) may inevitably be created as a result of the volatile reaction occurring within the reaction chamber.

### SUMMARY OF THE INVENTION

It is a general object of the present invention to provide a method of forming an improved high-K dielectric film and a method of fabricating a semiconductor film using such a high-K dielectric film.

More specifically, it is an object of the present invention to provide a method of forming a high-K dielectric film through MOCVD using an amine-based organic metal compound precursor that is capable of reducing the amount of residual carbon in the high-K dielectric film.

It is another object of the present invention to provide a method of forming a dielectric film using an amine-based organic metal compound precursor, the method including the steps of:
supplying a precursor gas including organic metal compound molecules of the amine-based organic metal compound precursor to a processing space that accommodates a substrate to be processed, a surface of the substrate being exposed in the processing space;
evacuating the precursor gas from the processing space after the precursor gas supplying step;
supplying a hydrogen gas on the surface of the substrate after the precursor gas evacuating step; and
introducing an oxidation gas into the processing space after the precursor gas evacuating step.

According to an aspect of the present invention, amine-based organic metal compound precursor molecules are adsorbed onto the surface of a substrate in a precursor gas supplying step, and the amine-based organic metal compound precursor molecules are evacuated from the surface of the substrate in a precursor gas evacuating step, after which a hydrogen gas supplying step is conducted so that carbon contained in a resulting metal film formed on the surface of the substrate that is made of a metal element contained in the organic metal precursor molecules may be efficiently removed to thereby obtain a high-K dielectric film that is substantially free of carbon. Then, by conducting an oxidation gas introducing step to realize an oxidation process on the metal film, a desirable dielectric film, particularly a high-K dielectric film, that has a low concentration of carbon and is free of halogen such as chloride may be formed. According to an aspect of the present invention, the amine-based organic metal compound precursor gas that may cause a volatile reaction with the hydrogen gas is removed from the surface of the substrate before the hydrogen supplying step is conducted so that particle generation may be prevented, for example.

### BRIEF DESCRIPTION OF THE DRAWINGS

FIG. 1 is a diagram showing an exemplary configuration of a MOCVD apparatus that is used in forming a high-K dielectric film according to an embodiment of the present invention;

FIG. 2 is a flowchart illustrating process steps of a method of forming a high-K dielectric film according to a first embodiment of the present invention;

FIG. 3 is a diagram illustrating a process sequence for forming a high-K dielectric film according to the first embodiment;

FIG. 4 is a diagram illustrating a process sequence for forming a high-K dielectric film according to a second embodiment of the present invention;

FIG. 5 is a diagram illustrating a process sequence for forming a high-K dielectric film according to a third embodiment of the present invention;

FIG. 6 is a diagram showing another exemplary configuration of a MOCVD apparatus that is used in forming a high-K dielectric film according to a fourth embodiment of the present invention;

FIG. 7 is a diagram illustrating a process sequence for forming a high-K dielectric film according to the fourth embodiment;

FIGS. 8A˜8D are diagrams illustrating process steps of fabricating a high-speed semiconductor device according to a fifth embodiment of the present invention;

FIGS. 9A˜9C are diagrams illustrating process steps of fabricating a MOS capacitor according to a sixth embodiment of the present invention; and

FIG. 10 is a diagram showing another exemplary configuration of a MOCVD apparatus according to a seventh embodiment of the present invention.

### DESCRIPTION OF THE PREFERRED EMBODIMENTS

In the following, preferred embodiments of the present invention are described with reference to the accompanying drawings.

### First Embodiment

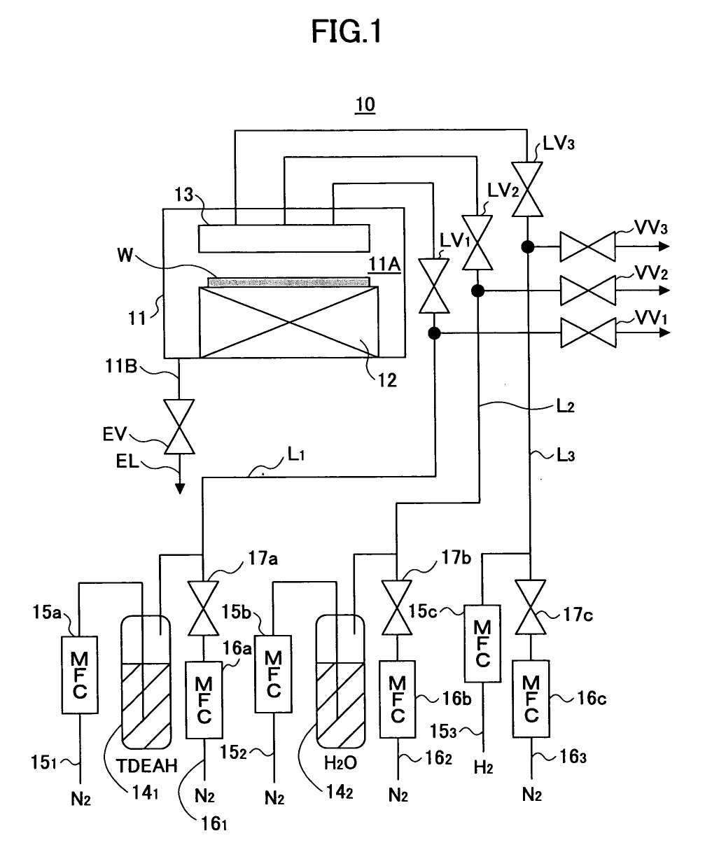

FIG. 1 is a diagram showing an exemplary configuration of a MOCVD apparatus that is used in forming a high-K dielectric film according to a first embodiment of the present invention.

The MOSCVD apparatus 10 shown in FIG. 1 includes a processing chamber 11 having a processing space 11A and an evacuation port 11B, and a substrate supporting member 12 that is provided within the processing space 11A. It is noted that a heat source such as a resistance heater or a heating lamp (not shown) is implemented in the substrate supporting member 12, which is arranged to support a substrate W that is subject to processing. The evacuation port 11B is connected to an evacuation line EL that includes an evacuation valve EV.

Also, it is noted that a shower head 13 made of quartz glass, for example, is provided within the processing space 11A. The shower head 13 is arranged to face against the substrate W being supported by the substrate supporting member 12. The shower head 13 is arranged to receive an organic metal compound precursor gas such as Hf[N(CH₃)₂]₄ (referred to as TDMAH hereinafter) from line L₁, an oxidation gas such as H₂O from line L₂, and a hydrogen gas from L₃, the respective gases being supplied to the shower head 13 along a with nitrogen carrier gases.

According to a specific example, TDMAH is stored in a precursor bottle 14₁, as a liquid precursor. A bubbling process is conducted on the TDMAH in the precursor bottle 14₁ by a nitrogen gas supplied from line 15₁ via a mass flow controller (MFC) 15a. The TDMAH gas generated in this manner is supplied to the shower head 13 via line L₁ along with a nitrogen carrier gas that is supplied from line 16₁ via a mass flow controller (MFC) 16a and a valve 17a.

Also, according to the present example, H₂O is stored in a precursor bottle 14₂ as a liquid precursor (i.e., water) A bubbling process is conducted on the H₂O in the precursor bottle 14₂ by a nitrogen gas supplied from line 15₂ via a mass flow controller (MFC) 15b. The H₂O gas generated in this manner is supplied to the shower head 13 via line L₂ along with a nitrogen carrier gas that is supplied from line 16₂ via a mass flow controller (MFC) 16b and a valve 17b.

Also, the hydrogen gas, which is supplied from a gas cylinder (not shown) via line 15₃ and a mass flow controller 15c, is supplied to the shower head 13 via line L₃ along with a nitrogen carrier gas that is supplied from line 16₃ via a mass flow controller 16c and a valve 17c.

It is noted that the lines L₁, L₂, and L₃ are provided with valves LV₁, LV₂, and LV₃, respectively. Also, a vent valve VV₁ is connected to the upstream side of the valve LV₁, a vent valve VV₂ is connected to the upstream side of the valve LV₂, and a vent valve VV₃ is connected to the upstream side of the valve LV₃.

According to the present example, the MOCVD apparatus 10 of FIG. 1 is used to form a HfO₂ film typically having a thickness of 2˜5 nm on the surface of the substrate W under a pressure of 133 Pa (1 Torr), at a substrate temperature of 200˜550° C.

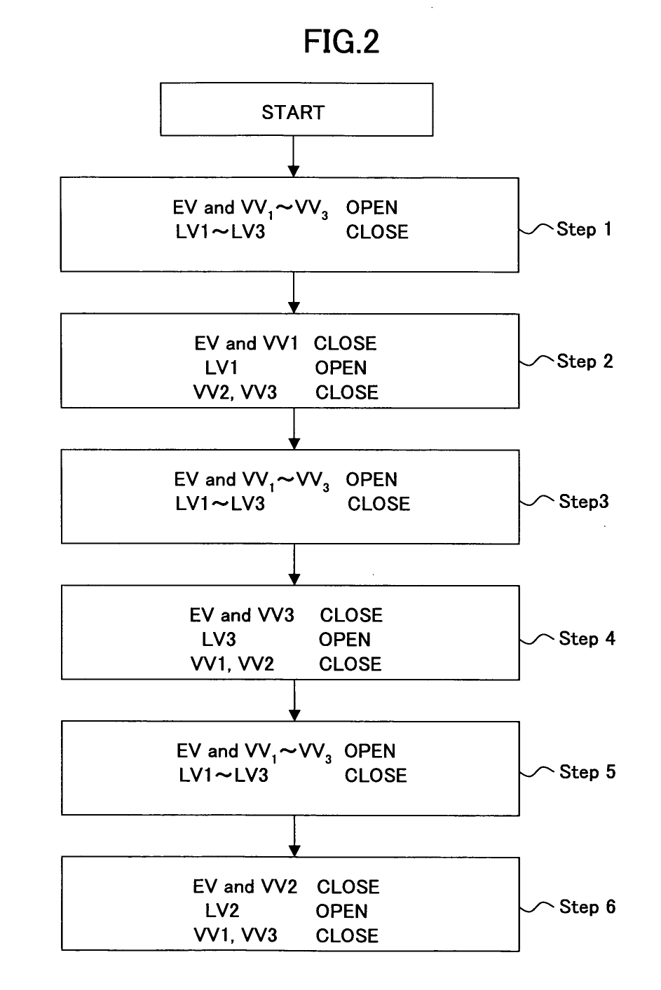

FIG. 2 is a flowchart showing process steps for forming a HfO₂ film using the MOCVD apparatus of FIG. 1.

According to FIG. 2, in step 1, the valves LV₁˜LV₃ are closed, and the evacuation valve EV is opened so that gas is evacuated from the processing space 11A of the processing chamber 11. Also, in this step, the vent valves VV₁˜VV₃ are opened so that gases contained in the lines L₁˜L₃ are discharged outside the system.

Then, in step 2, the evacuation valve EV and the vent valve VV₁ are closed, and the valve LV₁ is opened so that a precursor gas including TDMAH molecules is supplied to the processing space 11A via line L₁. As a result, the TDMAH molecules included in the precursor gas are chemically adsorbed onto the surface of the substrate W so that a precursor molecular layer that covers the surface of the substrate is formed.

Then, in step 3, the evacuation valve EV and the vent valves VV₁˜VV₃ are opened, and the valves LV₁˜LV₃ are closed so that gas is evacuated from the processing space 11A.

Then, in step 4, the evacuation valve EV and the vent valve VV₃ are closed, and the valve LV₃ is opened so that hydrogen gas in line 15₃ is supplied to the processing space 11A. The hydrogen gas supplied to the processing space 11A is typically attenuated to a concentration of around 3% by the nitrogen carrier gas in line 16₃.

The hydrogen gas supplied to the processing space 11A in the manner described above reacts with the TDMAH molecules adsorbed to the surface of the substrate W, the reaction corresponding to the reaction (1) described above. As a result, organic functional groups containing carbon are removed from the TDMAH molecules, and a layer made of the metal element Hf that covers the surface of the substrate W is formed.

Then, in step 5, the evacuation valve EV and the vent vales VV₁˜VV₃ are opened, and the valves LV₁˜LV₃ are closed so that gas is evacuated from the processing space 11A.

Then, in step 6, the evacuation valve EV and the vent valve VV₂ are closed and the valve LV₂ is opened so that H₂O gas is introduced into the processing space 11A from line L₂. The H₂O gas introduced to the processing space 11A causes oxidation of the metal Hf layer formed on the surface of the substrate W so that a HfO₂ film is formed.

After step 6, the process may go back to step 1 to open the evacuation valve EV and the vent valves VV₁˜VV₃, and close the valves LV₁˜LV₃ so that gas is evacuated from the processing space 11A.

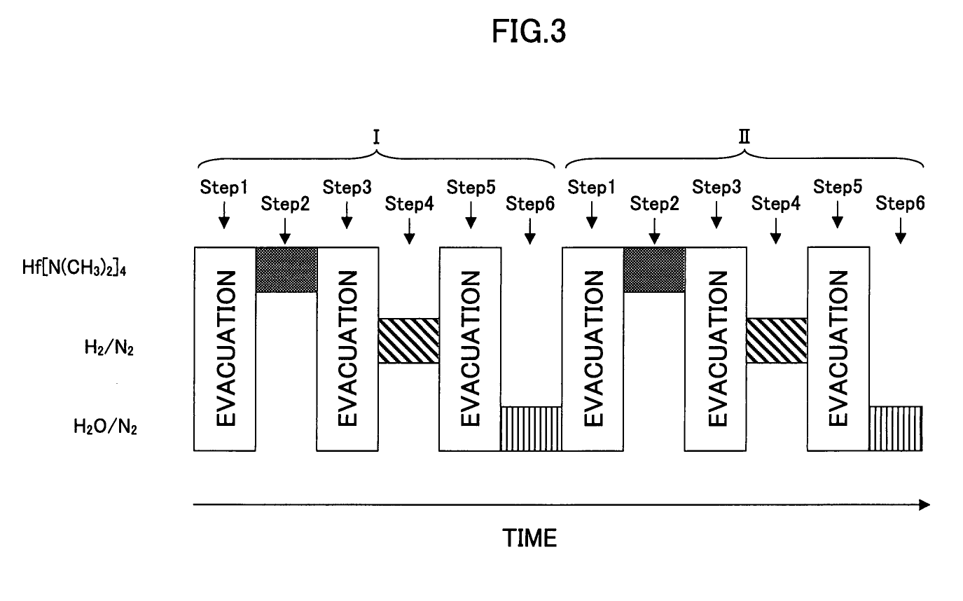

FIG. 3 is a diagram illustrating a process sequence for forming a high-K dielectric film according to an embodiment of the present invention.

As is shown in FIG. 3 the sequence of steps 1-6 of FIG. 2 may be repeatedly conducted as stages I, II, . . . , and so forth so that a HfO₂ film with the desired thickness of 2˜5 nm, for example, may be formed.

According to the present embodiment, after the TDMAH precursor introduction step 2, the evacuation step 3 is conducted, which is followed by the hydrogen gas introduction step 4. In this way, residual TDMAH precursor elements may be substantially removed from the processing space 11A before the hydrogen gas is introduced so that a volatile reaction between the hydrogen gas and the residual TDMAH precursor may be prevented and particle generation resulting from such a reaction may thereby be prevented. It is noted that the evacuation step 3 between the TDMAH precursor introduction step 2 and the hydrogen introduction step 4 may be conducted for period of around 1 second. It is also noted that in the evacuation step 3, a purge gas such as nitrogen gas or Ar gas may be introduced to the processing space 11A so that the discharging efficiency may be improved in discharging the residual TDMAH precursor.

According to the present embodiment, in the precipitation (hydrogen introduction) step 4 after the evacuation step 3, since the TDMAH precursor molecules adsorbed to the surface of the substrate W react with the introduced hydrogen gas to desorb the organic functional groups, the HfO₂ film formed in step 6 may be free from residual carbon. In this way, a high-quality HfO₂ film with little defects may be obtained using an organic metal compound precursor.

It is noted that according to an experiment conducted by the inventor of the present invention, the carbon concentration within a HfO₂ film formed according to the present embodiment is reduced to 1×10¹⁹ cm⁻³ or lower. Also, it is noted that the HfO₂ film formed in the above-described manner does not include halogen such as chloride since a chloride compound is not used as the precursor.

According to the above-described example, in the chemical adsorption step 2, a TDMAH layer having a one-molecule layer thickness is formed on the surface of the substrate W by controlling the TDMAH gas adsorption time or substrate temperature, and in the oxidation step 6, oxidation of the one-molecule thickness TDMAH film is realized to form a one-molecule thickness HfO₂ film. In this case, the processes illustrated in FIGS. 2 and 3 correspond to the so-called ALD (atomic layer deposition) process. However, the present invention is not limited to such an example, and in an alternative embodiment, the chemical adsorption step 2 may be arranged such that the TDMAH precursor is adsorbed to form a TDMAH layer having a plural-molecule layer thickness on the surface of the substrate W.

It is noted that in the above-described example, TDMAH is used as the amine-based organic metal compound precursor of the metal Hf. However, the present invention is not limited to such an example, and other materials such as tetrakis(diethylamino)hafnium (Hf[N(CH₂CH₃)₂]₄) may be used as an organic metal compound precursor of Hf.

It is also noted that the present invention is not limited to using an amine-based organic metal compound precursor of the metal element Hf, and in alternative embodiments, amine-based organic metal compound precursors of Zr such as tetrakis(dimethylamino)zirconium (Zr[N(CH₃)₂]₄) and tetrakis(diethylamino)zirconium (Hf[N(CH₂CH₃)₂]₄) may be used to form a ZrO₂ film, for example.

Further, the present invention is not limited to forming a HfO₂ film or a ZrO₂ film, and in alternative embodiments, a silicate film such as a HfSiO₄ film or a ZrSiO₄ film, or an aluminate film such as a HfAl₂O₄ film or a ZrAl₂O₄ film may be formed, for example. It is particularly noted that trimethylaluminum (Al(CH₃)₃) may be used as an organic metal compound precursor of Al, and tetrachlorosilane (SiCl₄) may be used as a precursor of Si.

In the case of forming a silicate film or an aliminate film, it is noted that a compound film with desirable characteristics may be formed by forming a HfO₂ molecular layer in stage I of the process sequence of FIG. 3, and forming a SiO₂ molecular layer or an Al₂O₃ molecular layer in stage II, for example.

It is noted that in fabricating a p-channel MOS transistor, after forming a polysilicon gate electrode, boron (B) contained in the gate electrode is diffused into the channel region during a thermal process that is subsequently performed, and as a result fluctuation occurs in the threshold voltage. In response to such a problem, typically, nitrogen (N) is introduced to a gate oxide film in order to prevent the diffusion of boron (B). According to the present embodiment in which an amine-based precursor is used, nitrogen may be readily introduced into the gate oxide film. For example, in the hydrogen gas introduction step (step 4 of FIGS. 2 and 3) of the present embodiment, ammonium (NH₃) gas at a concentration of around 1˜10% may be supplied so that nitrogen at a concentration of at least 1×10²¹ cm⁻³ may be contained in the resulting gate oxide film.

### Second Embodiment

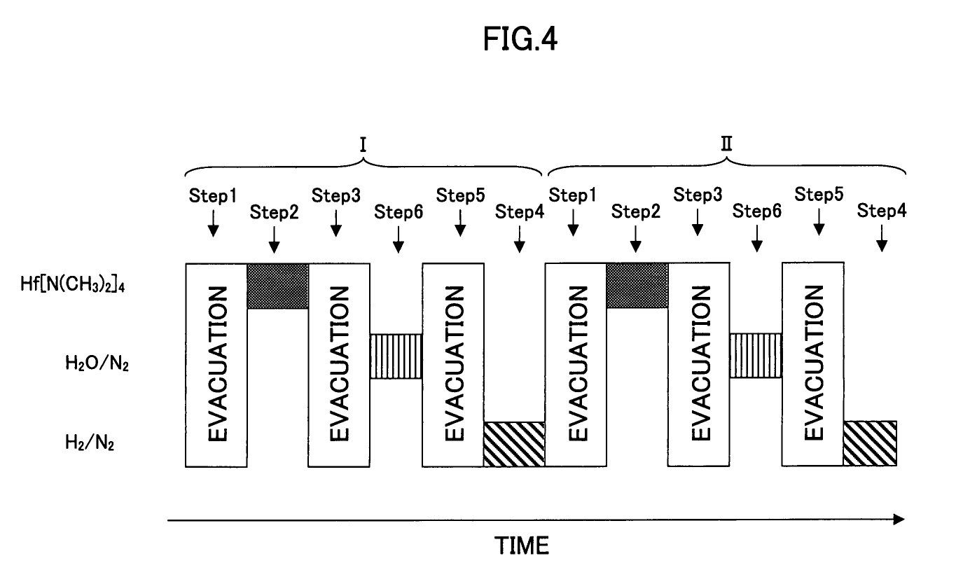

FIG. 4 is a diagram illustrating a process sequence for forming a HfO₂ film according to a second embodiment of the present invention.

In the process sequence of FIG. 4, steps 4 and 6 of FIG. 2 are interchanged so that the evacuation step 3 is immediately followed by the oxidation step 6, and after the oxidation step 6, the evacuation step 5 is conducted which is followed by the hydrogen gas introduction step 4.

According to the present example, in step 4, hydrogen molecules are adsorbed onto a HfO₂ film that is formed in the previous steps, and excessive hydrogen molecules are discharged from the processing space 11A in the evacuation step 1 of the next stage II.

Then, in step 2 of stage II, when an amine-based organic metal compound precursor of Hf such as TDMAH is introduced to the processing space 11A, the reaction (1) as is described above occurs when the TDMAH molecules are adsorbed onto the HfO₂ film formed in the previous steps so that organic functional groups is desorbed and the metal Hf is precipitated.

Then, after removing excessive TDMAH precursor molecules from the processing space 1A in step 3, oxidation is conducted on the metal Hf layer formed by the metal Hf adsorbed in step 6 so that a high-quality HfO₂ film with a low carbon concentration is formed.

It is noted that, as with the previously described embodiment, the present embodiment is not limited to using TDMAH as the amine-based organic metal compound precursor, and the film to be formed in the present embodiment is not limited to a HfO₂ film.

### Third Embodiment

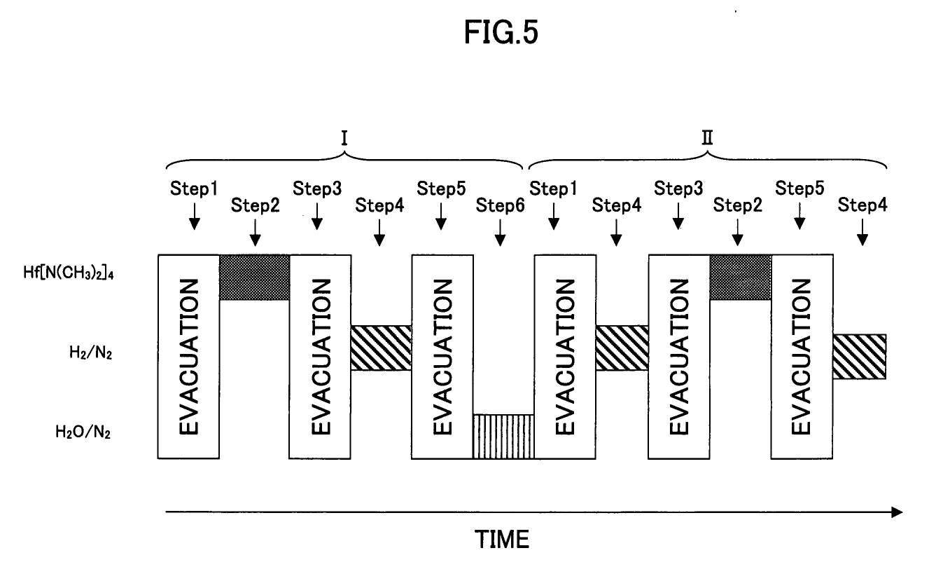

FIG. 5 is a diagram illustrating a process sequence for forming a HfO₂ film according to a third embodiment of the present invention.

In the process sequence of FIG. 5, in stage I, steps 1˜6 of FIG. 2 are conducted in consecutive order to form a first HfO₂ film, and in the next stage II, the evacuation step 1 is immediately followed by the hydrogen gas introduction step 4 after which the evacuation step 3 and the TDMAH introduction step 2 are conducted in this order.

Then, after conducting the TDMAH introduction step 2, the evacuation step 5 is conducted followed by the hydrogen gas introduction step 4.

As can be appreciated from the above descriptions, in the process sequence according to the present embodiment, the hydrogen gas introduction step is conducted before and after the amine-based organic metal compound precursor introduction step 2 to ensure the desorption of organic functional groups from the organic metal compound precursor molecules adsorbed on the substrate being processed. In this way, the amount of carbon remaining in the resulting high-K dielectric film (e.g., HfO₂ film) may be reduced.

### Fourth Embodiment

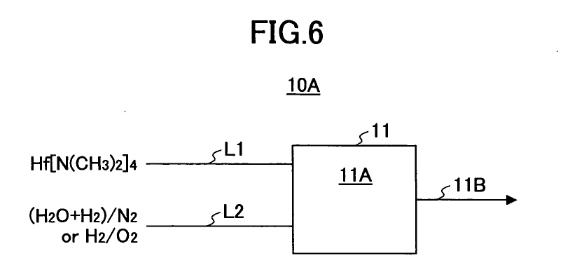

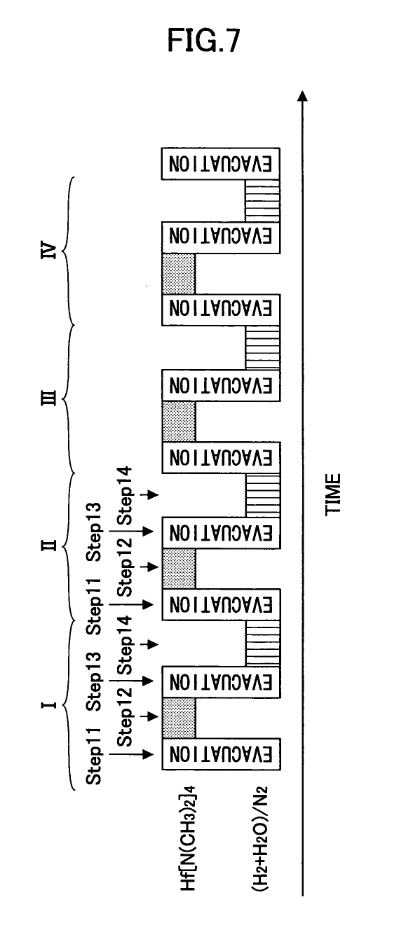

FIG. 6 is a diagram showing a simplified configuration of another MOCVD apparatus that is used in forming a high-K dielectric film according to a fourth embodiment of the present invention. FIG. 7 is diagram illustrating a process sequence for forming a HfO₂ film using the MOCVD apparatus of FIG. 6. It is noted that elements of the MOCVD apparatus 10A of FIG. 6 that are identical to those of the MOCVD apparatus 10 of FIG. 1 are assigned the same numerical references.

The MOCVD apparatus 10A of FIG. 6 differs from the MOCVD apparatus 10 of FIG. 1 in that it uses two gas supply lines L₁ and L₂ rather than three gas supply lines L₁, L₂, and L₃. Specifically, according to the present embodiment, line L₁ is used to supply TDMAH gas to the processing space 11A as in the previous embodiments and line L₂ is used to supply H₂O gas as well as hydrogen gas to the processing space 11A. In the following, operation processes of supplying H₂O gas and hydrogen gas to the processing space 11A using the gas supply line L₂ are described.

Referring to FIG. 7, first, gas is evacuated from the processing space 11A in step 11 after which TDMAH precursor gas is introduced to the processing space 11A via line L₁ in step 12. Then, in step 13, excessive TDMAH precursor gas is removed from the processing space 11A through evacuation.

Then, in step 14, H₂O gas and hydrogen gas are introduced into the processing space 11A along with nitrogen carrier gas via line L₂. As a result, oxidation is realized on the TDMAH molecular layer covering the surface of the substrate being processed in the processing space 11A, and at the same time, organic functional groups are desorbed.

It is noted that by repeatedly conducting the sequence of process steps 11˜14 as stages I, II, III, IV, . . . and so forth, a high-K dielectric film such as a HfO₂ film with a low carbon concentration may be efficiently formed on a substrate.

### Fifth Embodiment

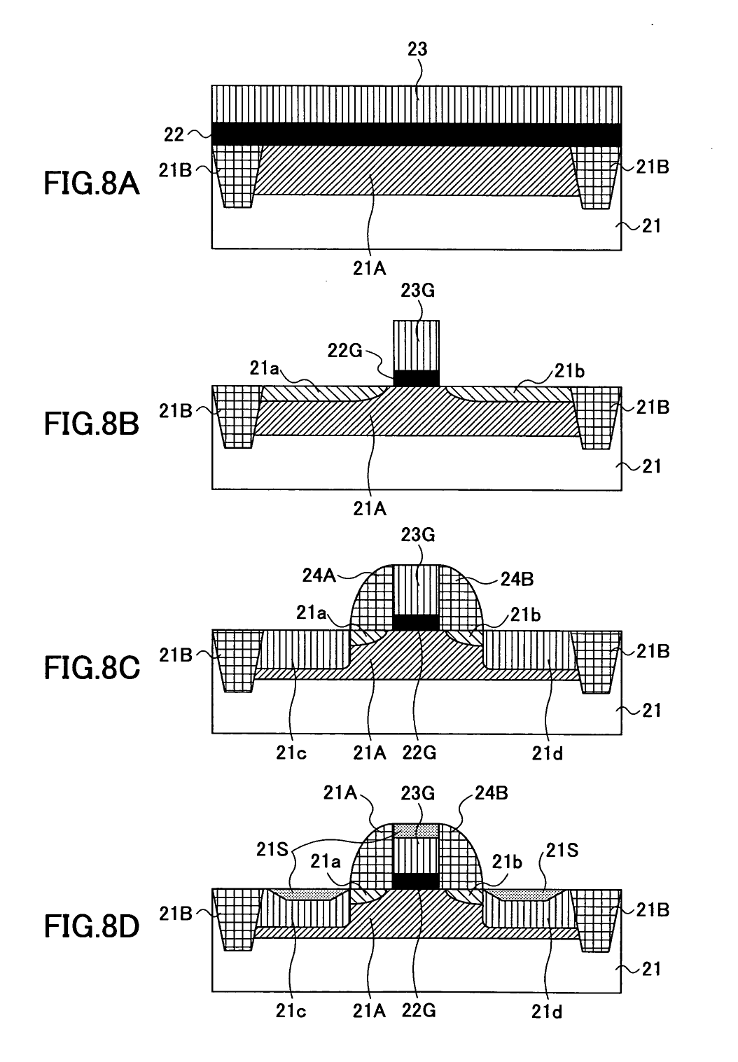

FIGS. 8A˜8D are diagrams showing process steps for fabricating a super-high-speed MOS transistor according to a fifth embodiment of the present invention.

According to the present embodiment, in the process step shown in FIG. 8A, a p-well region defined by an isolation region 21B is formed as an element region 21A on a silicon substrate 21, and the substrate 21 is introduced into a MOCDV apparatus (e.g., MOCVD apparatus 10 of FIG. 1, MOCVD apparatus 10A of FIG. 6) as the substrate W that is subject to processing.

By conducting any one of the process sequences described in relation to FIGS. 2 through 7 in the MOCVD apparatus, a gate dielectric film 22 corresponding to a high-K dielectric film that may be made of a metal oxide film such as a HfO₂ film, a ZrO₂ film, or an Al₂O₃ film, a silicate film, or an aluminate film, for example, is formed on the silicon substrate 21.

Also, in the process step illustrated in FIG. 8A, a polysilicon film 23 is formed over the gate dielectric film 22.

Then, in the process step of FIG. 8B, the polysilicon film 23 is patterned to form a polysilicon gate electrode pattern 23G. Then, using the polysislicon gate electrode as a mask, P (phosphorous) is implanted into the element region 21A through ion implantation so that diffusion regions 21a and 21b are formed at both sides of the gate electrode pattern 23G within the element region 21A. It is noted that in the patterning process of the polysilicon film 23, the high-K dielectric film 22 positioned underneath the polysilicon film 23 is also patterned into a shape identical to that of the polysilicon gate electrode pattern 23G, thereby resulting in the formation of a gate dielectric film pattern 22G.

Then, in the process step of FIG. 8C, side wall insulating films 24A and 24B are formed on side wall surfaces of the gate electrode pattern 23G. The gate electrode pattern 23G and the side wall insulating films 24A and 24B are used as masks to conduct ion implantation of P at an accelerating speed and a dosage that are greater than those used in the process step of FIG. 8B so that n-type diffusion regions 21c and 21d are formed in the element region 21A at the outer sides of the side wall insulating films 24A and 24B. It is noted that the n-type diffusion regions 21c and 21d are arranged to partially cover the diffusion regions 21a and 21b, respectively.

Then, in the process step of FIG. 8D, a metal layer such as a Co layer is deposited onto the structure of FIG. 8C, and a thermal process is conducted for a short period of time, after which the metal film is removed. In this way, silicide regions 21S are formed on the surfaces of the diffusion regions 21c and 21d as well as the surface of the gate electrode pattern 23G.

The MOS transistor formed in the manner described above uses a high-K dielectric film such as a HfO₂ film as the gate dielectric film 22G. Thereby, even in a case where the gate length is reduced to 0.1 μm or less, the gate dielectric film may still have a sufficient physical film thickness so that an increase of gate leak currents may be prevented. Also, it is noted that since the carbon concentration in the gate dielectric film 22G is reduced according to the present embodiment, a highly reliable film that is free of defects such as voids may be formed.

### Sixth Embodiment

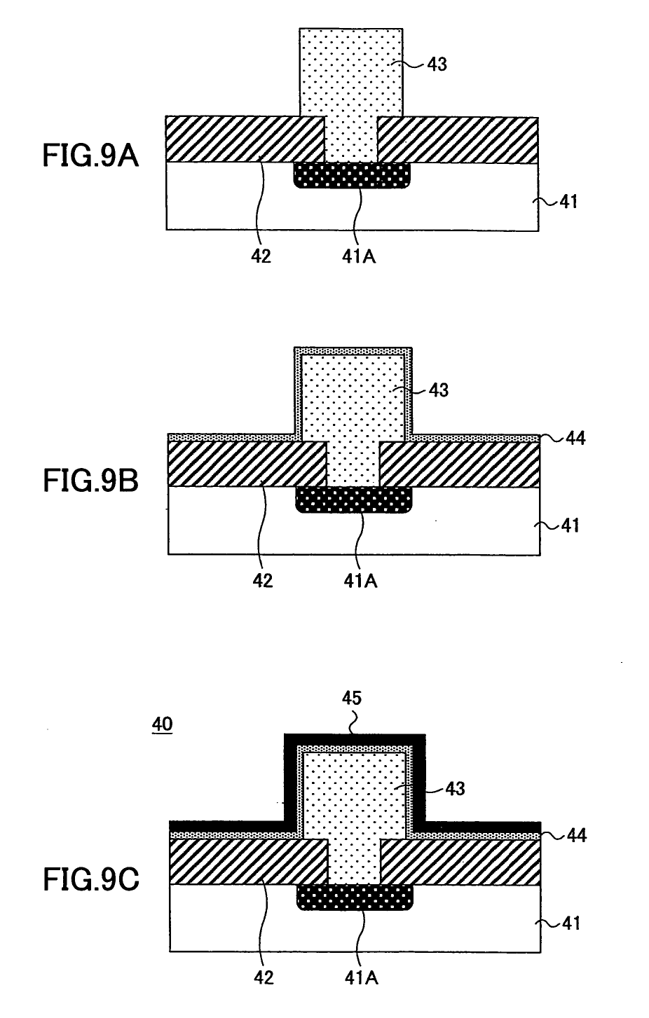

FIGS. 9A˜9C are diagrams showing process steps for fabricating a MOS capacitor according to a sixth embodiment of the present invention.

According to the present embodiment, in the process step as is shown in FIG. 9A, an insulating film 42 corresponding to a silicon oxide film, for example, is formed on a silicon substrate 41 that includes a diffusion region 41A. Also, a contact hole that exposes the diffusion region 41A is formed on the insulting film 42.

Then, a polysilicon lower electrode 43 that is doped by a p-type or n-type impurity according to the conductivity type of the diffusion region 41A is formed on the insulating film 42. The polysilicon lower electrode 43 is arranged to come into contact with the diffusion region 41A via the contact hole formed on the insulating film 42.

Then, in the process step of FIG. 9B, the silicon substrate 41 of FIG. 9A is introduced into the processing chamber 11 of a MOCVD apparatus (e.g., MOCVD apparatus 10 of FIG. 1, MOCVD apparatus 10A of FIG. 6) as the substrate W that is subject to processing. Then, any one of the process sequences illustrated in FIGS. 2 though 7 may be conducted to form a high-K dielectric film (e.g., HfO₂ film) as a capacitor dielectric film 44 having a film thickness of 2˜3 nm on the surface of the polysilicon lower electrode 43.

Then, in the process step of FIG. 9C, a polysilicon upper electrode 44 is formed on the capacitor dielectric film 44 so that a MOS capacitor 40 is formed.

According to the present embodiment, in the high-K dielectric film such as a HfO₂ film that is used as the capacitor dielectric film 44, the concentration of an impurity such as carbon derived from the organic metal compound precursor is reduced so that a highly reliable film capable of effectively preventing the generation of leak currents is realized. It is noted that by incorporating the carbon removal step, the generation of voids in the dielectric film as a result of oxidation of carbon within the dielectric film may be effectively prevented. In this way, electric field concentration occurring at the voids may be prevented.

Also, it is noted that in the present embodiment, the capacitor dielectric film 44 is formed through adsorption of an organic metal compound precursor gas and oxidation of a resulting metal film. Accordingly, the capacitor dielectric film 44 may be evenly formed at a uniform film thickness even when the lower electrode 43 has a complicated structure.

The capacitor formed in the above-described manner may be used to construct a DRAM, for example.

### Seventh Embodiment

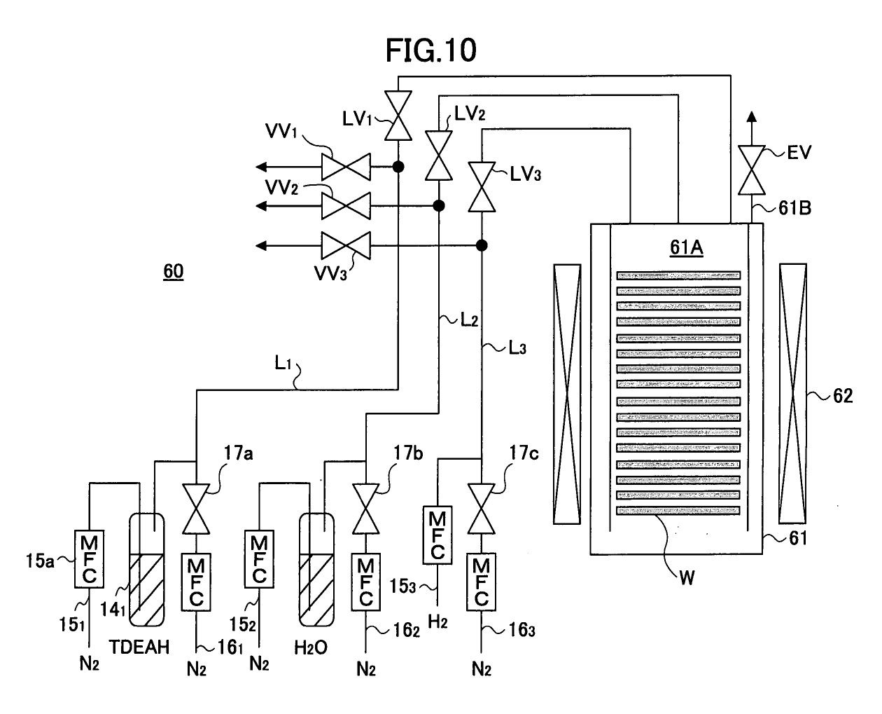

FIG. 10 is a diagram showing a configuration of a MOCVD apparatus 60 according to a seventh embodiment of the present invention. It is noted that elements shown in FIG. 10 that are identical to those shown in FIG. 1 are assigned the same numerical references and their descriptions are omitted.

The MOCVD apparatus 60 of FIG. 10 is arranged to realize batch processing of plural substrates W. The MOCVD apparatus 60 includes a processing chamber 61 having a processing space 61A that is arranged to accommodate plural substrates W that are subject to processing.

The processing chamber 61 also has an evacuation port 61B from which gas is evacuated via an evacuation valve EV. Also, a heater 62 is provided at the outer side of the processing chamber 61.

The batch processing MOCVD apparatus 60 as is described above includes lines L₁, L₂, and L₃ for supplying an amine-based organic metal compound precursor such as TDMAH, an oxidizing agent such as H₂O, and hydrogen gas, respectively. By alternatingly supplying the respective gases according to any one of the process sequences described in relation to FIGS. 2˜7, volatile reaction may be prevented from occurring within the processing chamber 61 and organic functional groups may be effectively removed from the organic metal compound precursor so that the carbon concentration within the resulting high-K dielectric film may be effectively reduced.

According to an embodiment of the present invention, amine-based organic metal compound precursor molecules are adsorbed onto the surface of a substrate being processed after which the residual amine-based organic metal compound precursor molecules are evacuated from the surface of the substrate, and then the adsorbed amine-based organic metal compound precursor molecules are reacted with hydrogen gas so that a film made of a metal element included in the organic metal compound precursor is formed to cover the surface of the substrate. By forming the metal film in the manner described above, carbon may be effectively removed from the film so that the resulting metal film may be substantially free of carbon. Then, an oxidation process is conducted on this metal film to form a desired dielectric film. According to the present embodiment, the amine-based organic metal compound precursor gas that may cause volatile reaction with hydrogen gas is removed from the processing space of the substrate before the hydrogen gas reaction process is conducted so that particle generation may be prevented, for example.

Further, it is noted that the present invention is not limited to the specific embodiments described above, and variations and modifications may be made without departing from the scope of the present invention.

1. A method of forming a dielectric film using an amine-based organic metal compound precursor, the method comprising the steps of:
supplying a precursor gas including organic metal compound molecules of the amine-based organic metal compound precursor to a processing space that accommodates a substrate to be processed, a surface of the substrate being exposed in the processing space;
evacuating the precursor gas from the processing space after the precursor gas supplying step;
supplying a hydrogen gas on the surface of the substrate after the precursor gas evacuating step; and
introducing an oxidation gas into the processing space after the precursor gas evacuating step.

2. The method of forming a dielectric film as claimed in claim 1, wherein the oxidation gas introducing step is conducted after the hydrogen gas supplying step.

3. The method of forming a dielectric film as claimed in claim 1, wherein the oxidation gas introducing step and the hydrogen gas supplying step are conducted simultaneously.

4. The method of forming a dielectric film as claimed in claim 1, wherein the oxidation gas introducing step is conducted before the hydrogen gas supplying step.

5. The method of forming a dielectric film as claimed in claim 1, wherein the precursor gas supplying step, the precursor gas evacuating step, the hydrogen gas supplying step, and the oxidation gas introducing step are repeatedly conducted.

6. The method of forming a dielectric film as claimed in claim 1, further comprising the steps of:
supplying the hydrogen gas to the processing space before the precursor supplying step; and
evacuating the hydrogen gas from the processing space.

7. The method of forming a dielectric film as claimed in claim 6, further comprising a step of:
introducing the oxidation gas to the processing space before the hydrogen gas supplying step that is conducted before the precursor gas supplying step.

8. The method of forming a dielectric film as claimed in claim 6, wherein the hydrogen gas supplying step conducted before the precursor gas supplying step, the hydrogen gas evacuating step, the precursor gas supplying step, the precursor gas evacuating step, the hydrogen gas supplying step, and the oxidation gas introducing step are repeatedly conducted.

9. The method of forming a dielectric film as claimed in claim 1, wherein the precursor gas supplying step includes forming an organic metal compound molecular layer covering the surface of the substrate using the organic metal compound molecules, the molecular layer having a thickness corresponding to a thickness of a plural-molecule layer.

10. The method of forming a dielectric film as claimed in claim 1, wherein the precursor gas supplying step includes forming an organic metal compound molecular layer covering the surface of the substrate using the organic metal compound molecules, the molecular layer having a thickness corresponding to a thickness of a single-molecule layer.

11. The method of forming a dielectric film as claimed in claim 1, wherein the amine-based organic metal compound precursor includes at least one of Hf, Zr, Si, Al, and Ti as a metal element.

12. The method of forming a dielectric film as claimed in claim 1, wherein the dielectric film is formed by a metal oxide of Hf, Zr, or Al, a silicate, or an aluminate.

13. The method of forming a dielectric film as claimed in claim 12, wherein the dielectric film corresponds a HfO₂ film or a ZrO₂ film.

14. The method of forming a dielectric film as claimed in claim 1, wherein the amine-based organic metal compound precursor includes at least one of a methylamino group, a ethylamino group, and methylethylamino group.

15. The method of forming a dielectric film as claimed in claim 14, wherein the amine-based organic metal compound precursor corresponds to tetrakis(dimethylamino)hafnium or tetrakis(dimethylamino)zirconium.

16. A method of fabricating a semiconductor device, the method comprising the steps of:
forming a gate dielectric film on a substrate;
forming a gate electrode on the gate dielectric film; and
introducing an impurity element into the substrate using the gate electrode as a mask;
wherein the gate electrode forming step includes
supplying a precursor gas including organic metal compound molecules of an amine-based organic metal compound precursor to a processing space that accommodates the substrate;
evacuating the precursor gas from the processing space after the precursor gas supplying step;
supplying hydrogen gas on a surface of the substrate after the precursor gas evacuating step; and
introducing an oxidation gas into the processing space after the precursor gas evacuating step.

17. A method of fabricating a capacitor, the method composing the steps of:
forming a capacitor lower electrode on a substrate;
forming a capacitor dielectric film on the lower electrode; and
forming an upper electrode on the capacitor dielectric;
wherein the capacitor dielectric forming step includes
supplying a precursor gas including organic metal compound molecules of an amine-based organic metal compound precursor to a processing space that accommodates the substrate;
evacuating the precursor gas from the processing space after the precursor gas supplying step;
supplying hydrogen gas on a surface of the substrate after the precursor gas evacuating step; and
introducing an oxidation gas in the processing space after the precursor gas evacuating step.
